(19) United States
(12) Patent Application Publication
(10) Pub. No.: US 2026/0238164 A1
(43) Pub. Date: Aug. 13, 2026

(54) THREE STAGE POWER AMPLIFIER WITH BALANCED DRIVER STAGE

(71) Applicant: AXIRO SEMICONDUCTOR INC., San Diego, CA (US)

(72) Inventors: Ramzi DARRAJI, Ottawa (CA); Prathamesh Hirachandra PEDNEKAR, Bengaluru (IN); Ramanujam SRINIDHI EMBAR, San Diego, CA (US)

(73) Assignee: AXIRO SEMICONDUCTOR INC., San Diego, CA (US)

(21) Appl. No.: 19/050,436

(22) Filed: Feb. 11, 2025

(51) Int. Cl. H03F 1/02; H03F 1/56; H03F 3/24; H04B 1/04

(52) U.S. Cl. CPC H03F 1/0288; H03F 1/56; H03F 3/245; H04B 1/04; H03F 2200/222; H03F 2200/387; H03F 2200/451; H04B 2001/045

(57) ABSTRACT

Systems and circuits implementing an amplifier module are described. An integrated circuit can include a pre-driver stage, a driver stage and a final stage. The pre-driver stage can amplify an input signal to generate a first amplified signal. The driver stage can split the first amplified signal into first and second intermediate signals out-of-phase with each other. The driver stage can absorb reflections from mismatches between the first and second intermediate signals. The driver stage can amplify the first and second intermediate signals to generate first and second amplified intermediate signals, respectively, out-of-phase with each other. The driver stage can absorb reflections from mismatches between the first and second amplified intermediate signals. The driver stage can combine the first and second intermediate amplified signals to generate a second amplified signal. The final stage can amplify the second amplified signal to generate an output amplified signal.

### BACKGROUND

The present disclosure relates in general to power amplification systems and devices. Particularly, a three stage amplifier with balanced driver stage is described.

Wireless communication systems may employ power amplifiers for increasing the power of radio frequency (RF) signals. In a wireless communication system, a power amplifier in a final amplification stage of a transmission channel may facilitate amplification of a signal to an antenna for radiation over the air. High gain, high linearity, stability, and a high level of power-added efficiency are characteristics of a desirable amplifier in such a wireless communication system. In general, a power amplifier may operate at maximum power efficiency when the power amplifier transmits close to saturated power. However, power efficiency may degrade as output power decreases. Therefore, a high efficiency power amplifier architecture may be desirable for current and next-generation wireless systems.

### SUMMARY

In one embodiment, an integrated circuit implementing an amplifier module is generally described. The integrated circuit can include a pre-driver stage, a driver stage and a final stage. The pre-driver stage can be configured to amplify an input signal to generate a first amplified signal. The driver stage can be configured to split the first amplified signal into a first intermediate signal and a second intermediate signal. The first intermediate signal and the second intermediate signal can be out-of-phase with each other. The driver stage can be further configured to absorb reflections resulted from mismatches between the first intermediate signal and the second intermediate signal. The driver stage can be further configured to amplify the first intermediate signal to generate a first amplified intermediate signal. The driver stage can be further configured to amplify the second intermediate signal to generate a second amplified intermediate signal. The first amplified intermediate signal and the second amplified intermediate signal can be out-of-phase with each other. The driver stage can be further configured to absorb reflections resulted from mismatches between the first amplified intermediate signal and the second amplified intermediate signal. The driver stage can be further configured to combine the first amplified intermediate signal and the second intermediate amplified signal to generate a second amplified signal. The final stage can be configured to amplify the second amplified signal to generate an output amplified signal.

In one embodiment, a system implementing a data transmitter is generally described. The system can include a plurality of antennas and a plurality of transmission channels. A transmission channel can include an amplifier module comprising a pre-driver stage, a driver stage and a final stage. The pre-driver stage can be configured to amplify an input signal to generate a first amplified signal. The driver stage can be configured to split the first amplified signal into a first intermediate signal and a second intermediate signal. The first intermediate signal and the second intermediate signal can be out-of-phase with each other. The driver stage can be further configured to absorb reflections resulted from mismatches between the first intermediate signal and the second intermediate signal. The driver stage can be further configured to amplify the first intermediate signal to generate a first amplified intermediate signal. The driver stage can be further configured to amplify the second intermediate signal to generate a second amplified intermediate signal. The first amplified intermediate signal and the second amplified intermediate signal can be out-of-phase with each other. The driver stage can be further configured to absorb reflections resulted from mismatches between the first amplified intermediate signal and the second amplified intermediate signal. The driver stage can be further configured to combine the first amplified intermediate signal and the second intermediate amplified signal to generate a second amplified signal. The final stage can be configured to amplify the second amplified signal to generate an output amplified signal. The final stage can be further configured to output the output amplified signal to an antenna among the plurality of antennas.

In one embodiment, a system implementing a data transceiver is generally described. The system can include a plurality of antennas, a plurality of receiver channels and a plurality of transmission channels. The plurality of receiver channels can be configured to process signals being received by the plurality of antennas. A transmission channel can include an amplifier module comprising a pre-driver stage, a driver stage and a final stage. The pre-driver stage can be configured to amplify an input signal to generate a first amplified signal. The driver stage can be configured to split the first amplified signal into a first intermediate signal and a second intermediate signal. The first intermediate signal and the second intermediate signal can be out-of-phase with each other. The driver stage can be further configured to absorb reflections resulted from mismatches between the first intermediate signal and the second intermediate signal. The driver stage can be further configured to amplify the first intermediate signal to generate a first amplified intermediate signal. The driver stage can be further configured to amplify the second intermediate signal to generate a second amplified intermediate signal. The first amplified intermediate signal and the second amplified intermediate signal can be out-of-phase with each other. The driver stage can be further configured to absorb reflections resulted from mismatches between the first amplified intermediate signal and the second amplified intermediate signal. The driver stage can be further configured to combine the first amplified intermediate signal and the second intermediate amplified signal to generate a second amplified signal. The final stage can be configured to amplify the second amplified signal to generate an output amplified signal. The final stage can be further configured to output the output amplified signal to an antenna among the plurality of antennas.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a diagram showing an example system that can implement three stage power amplifier with balanced driver stage in one embodiment.

FIG. 2 is a diagram showing another example system that can implement three stage power amplifier with balanced driver stage in one embodiment.

FIG. 3 is a diagram showing an example of a three stage power amplifier with balanced driver stage in one embodiment.

FIG. 4 is a diagram showing details of a three stage power amplifier with balanced driver stage in one embodiment.

FIG. 5 is a diagram showing another example implementation of a balanced driver stage of a three stage power amplifier with balanced driver stage in one embodiment.

FIG. 6 is a diagram showing an example implementation of a final stage of a three stage power amplifier with balanced driver stage in one embodiment.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

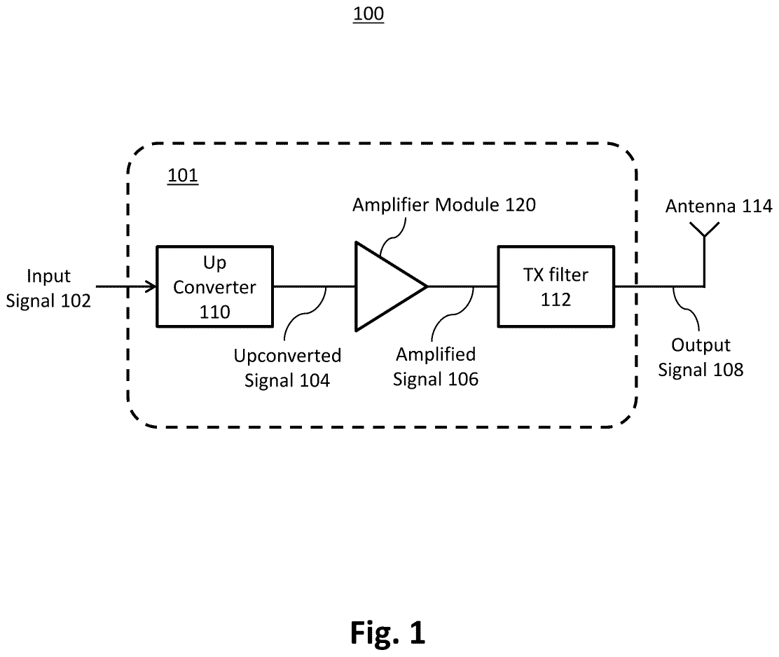

FIG. 1 is a diagram showing an example system that can implement a three stage power amplifier with balanced driver stage in one embodiment. System 100 in FIG. 1 can be part of a radio frequency (RF) transmitter, or other types of RF transmission devices such as beamforming integrated circuits (ICs), that includes a plurality of communication channels connected to a phased array including a plurality of antenna elements. A communication channel 101 among the plurality of communication channels in system 100 and an antenna 114 among the phased array are shown in FIG. 1. Communication channel 101 can be implemented by one or more semiconductor devices.

Communication channel 101 can include at least an upconverter 110, an amplifier module 120 and a transmission (TX) filter 112. An input signal 102 encoding data representing information and/or messages can be provided to communication channel 101. Communication channel 101 can upconvert, amplify and filter input signal 102 to generate an output signal 108 encoding the same data as input signal 102. Output signal 108 can be RF signals. Output signal 108 can be provided to an antenna 114 and antenna 114 can emit radio waves representing output signal 108 to wirelessly transmit output signal 108 to a destination device through a medium, such as air.

Upconverter 110 can receive input signal 102. Upconverter 110 can be configured to convert input signal 102 into an upconverted signal 204 that has a higher frequency than input signal 202. Amplifier module 120 can receive upconverted signal 104 from upconverter 110. Amplifier module 120 can be a power amplifier configured to amplify upconverted signal 104 into an amplified signal 106. Amplifier module 120 can boost the signal strength or gain, or increase the power level, of upconverted signal 104 to a level suitable for transmission over long distances or through various mediums. The increased signal strength can also extend the coverage area of the RF transmitter including communication channel 101, allowing RF waves emitted from antenna 114 to cover relatively larger geographical areas. Amplifier module 120 can also match the impedance of communication channel 101 to the impedance of antenna 114 for maximum power transfer and optimizing the efficiency of the transmission.

TX filter 112 can receive amplified signal 106. TX filter 112 can be configured to suppress harmonics in amplified signal 106 (e.g., harmonics may be generated by amplifier module 120), filter out unwanted frequencies (e.g., frequencies different from the carrier frequency) and attenuate noise that might be present in amplified signal 106 to improve SNR. The filtered version of amplified signal 106 can be outputted by TX filter 112 as output signal 108.

In an aspect, conventional systems can implement amplifier module 120 using a two-stage power amplifier that includes a driver stage for boosting signal amplitude and an output or final stage for optimizing efficiency. An amount of gain boost from a two-stage power amplifier can be defined and limited depending on the device types and sizes in the driver stage and final stage. In an aspect, to increase the amount of the gain boost by the two-stage power amplifier, a pre-driver can be connected to the input of the two-stage power amplifier to provide a relatively small boost to the signal before the signal be inputted to the driver stage of the power amplifier. In these conventional systems, the pre-driver can be a separate chip external to the two-stage power amplifier chip. However, the added pre-driver can sometimes create reflections towards the pre-driver from the driver stage of the power amplifier, causing mismatch and creation of standing waves. As a result of these reflections, not the entire signal may pass through into the power amplifier and the overall performance can be degraded. Some conventional systems address the reflections by adding an isolator or circulator between the pre-driver and the power amplifier, but the added isolator increases costs and real estate of the circuit board.

To be described herein, to address the limited gain boost in conventional two-stage power amplifiers and the deficiencies of the added pre-driver and isolators in conventional systems, amplifier module 120 can be implemented as a three-stage amplifier. The three-stage amplifier described herein can include a pre-driver stage, a driver stage, and an output or final stage integrated in the same chip. To absorb or to integrate the pre-driver with the driver stage and output stage, the driver stage in the three-stage power amplifier can be implemented with a balanced architecture where the driver stage can present a high absorption load to the pre-driver stage to eliminate reflection from the driver stage to the pre-driver stage, thus eliminating the need for an isolator.

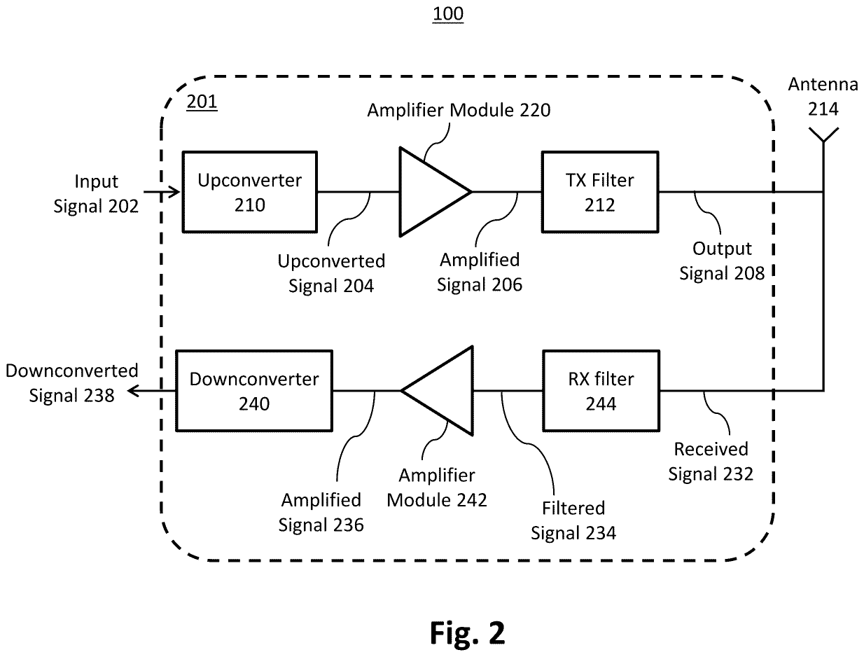

FIG. 2 is a diagram showing another example system that can implement a three stage power amplifier with balanced driver stage in one embodiment. Descriptions of FIG. 2 can reference components shown in FIG. 1. System 200 in FIG. 2 can be part of a radio frequency (RF) transceiver, or other types of RF communication devices such as beamforming integrated circuits (ICs), that includes a plurality of communication channels connected to a phased array including a plurality of antenna elements. A communication channel 201 among the plurality of communication channels in system 200 and an antenna 218 among the phased array are shown in FIG. 2. Communication channel 201 can be implemented by one or more semiconductor devices.

Communication channel 201 can include a transmitter path and a receiver path. The transmitter path can be implemented for generating signals to be transmitted from antenna 214 and the receiver path can be implemented for processing signals received by antenna 214. The transmitter path can include at least an upconverter 210, an amplifier module 220 and a transmission (TX) filter 212. An input signal 202 encoding data representing information and/or messages can be provided to communication channel 201. Communication channel 201 can upconvert, amplify and filter input signal 202 to generate an output signal 208 encoding the same data as input signal 202. Output signal 208 can be RF signals. Output signal 208 can be provided to an antenna 214 and antenna 214 can emit radio waves representing output signal 208 to wirelessly transmit output signal 208 to a destination device through a medium, such as air.

Upconverter 210 can receive input signal 202. Upconverter 210 can be configured to convert input signal 202 into an upconverted signal 204 that has a higher frequency than input signal 202. Amplifier module 220 can receive upconverted signal 204 from upconverter 210. Amplifier module 220 can be a power amplifier configured to amplify upconverted signal 204 into an amplified signal 206. Amplifier module 220 can boost the signal strength or gain, or increase the power level, of upconverted signal 204 to a level suitable for transmission over long distances or through various mediums. The increased signal strength can also extend the coverage area of the RF transmitter including communication channel 201, allowing RF waves emitted from antenna 214 to cover relatively larger geographical areas. Amplifier module 220 can also match the impedance of communication channel 201 to the impedance of antenna 214 for maximum power transfer and optimizing the efficiency of the transmission.

TX filter 212 can receive amplified signal 206. TX filter 212 can be configured to suppress harmonics in amplified signal 206 (e.g., harmonics may be generated by amplifier module 220), filter out unwanted frequencies (e.g., frequencies different from the carrier frequency) and attenuate noise that might be present in amplified signal 206 to improve SNR. The filtered version of amplified signal 206 can be outputted by TX filter 212 as output signal 208.

The receiver path can include at least a downconverter 240, an amplifier module 242 and a receiver (RX) filter 244. Antenna 214 can receive a received signal 232 encoding data representing information and/or messages. Communication channel 201 can filter, amplify and downconvert received signal 232 to generate a downconverted signal 238 encoding the same data as received signal 232. Received signal 232 can be a RF signal.

RX filter 244 can receive received signal 232. RX filter 244 can be configured to filter out unwanted frequencies and attenuate noise that might be present in received signal 232 to generate filtered signal 234. Filtering received signal 232 to generate filtered signal 234 can also provide protection to amplifier module 242 by filtering out excessively strong out-of-band signals or signals with high levels of interference since amplifying such signals can risk damaging amplifier module 242.

Amplifier module 242 can receive filtered signal 234. Amplifier module 242 can be a low power amplifier configured to amplify signals with relatively low power levels. Using a low power amplifier in the receiver path can amplify filtered signal 234 to a level that can be processed by subsequent stages of the receiver path, such as downconverter 240, without introducing excessive noise or distortion. Also, using a low power amplifier in the receiver path can incur relatively less cost when compared to higher power amplifiers. Amplifier module 242 can amplify filtered signal 234 to generate an amplified signal 236. Downconverter 240 can receive amplified signal 236. Downconverter 240 can be configured to convert amplified signal 236 into a downconverted signal 238 that has a lower frequency than input signal 202. Downconverter 240 can send downconverted signal 238 to a controller or processor for further decoding.

Amplifier module 220 shown in FIG. 2 can be identical to amplifier module 120 shown in FIG. 1. Amplifier module 220, similar to amplifier module 120, can be implemented as a three-stage amplifier to address the limited gain boost in conventional two-stage power amplifiers and the deficiencies of the added pre-driver and isolators in conventional systems. The three-stage amplifier described herein including a pre-driver stage, a driver stage with balanced driver architecture, and an output or final stage integrated in the same chip can be applicable to RF transmitters (e.g., system 100) and/or RF transceivers (e.g., system 200).

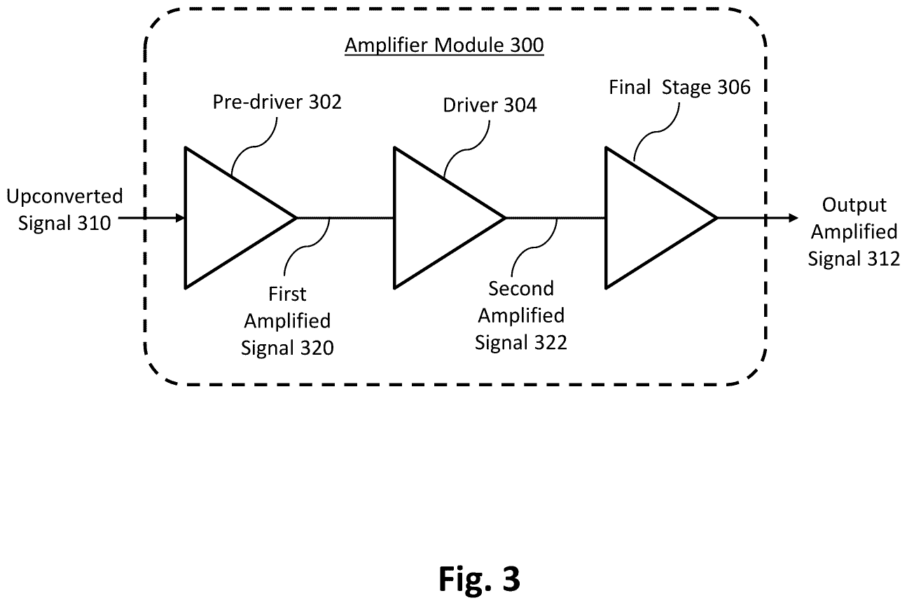

FIG. 3 is a diagram showing an example of a three stage power amplifier with balanced driver stage in one embodiment. Descriptions of FIG. 3 can reference components shown in FIG. 1 and FIG. 2. An amplifier module 300 is shown in FIG. 3. Amplifier module 300 can be an implementation of amplifier module 120 in FIG. 1 and/or amplifier module 220 in FIG. 2. Amplifier module 300 can be a three stage amplifier including a pre-diver stage 302 (“pre-driver 302”), a driver stage 304 (“driver 304”) and a final stage 306 (can also be referred to as output stage). Amplifier module 300 can receive an upconverted signal 310 and amplify upconverted signal 310 to generate an output amplified signal 312, where output amplified signal 312 has a higher signal strength than upconverted signal 310. The difference in signal strengths between upconverted signal 310 and output amplified signal 312 can be dependent on the gain of amplifier module 300. Upconverted signal 310 can be upconverted signal 104 in FIG. 1 or upconverted signal 204 in FIG. 2, and output amplified signal 312 an be amplified signal 106 in FIG. 1 or amplified signal 206 in FIG. 2. Amplifier module 300 can be an integrated circuit (IC) implemented by semiconductor devices, and pre-diver stage 302, driver stage 304 and final stage 306 can be integrated in the same IC.

In an aspect, the signal level of a signal is the strength or intensity of the signal that can be measured in decibels (dB) or volts. The signal level of a signal can indicate how strong or weak a signal is at a particular point in a system. For example, in audio applications, the signal level of an audio signal can be referred to as the volume of a sound. On the other hand, a gain of a signal is an amount of increase in amplitude or power of the signal in response to being processed by an amplifier or other components configured to amplify signals. The gain an be a measure of how much an amplifier amplifies or boosts a signal compared to its input.

Pre-driver 302 can be configured to process upconverted signal before driver stage 304 performs amplification. In one or more embodiments, pre-driver 302 can be configured to boost the signal level of upconverted signal 210 to a signal level suitable for driver stage 304 to amplify without distortion. The boosted signal generated by pre-driver 302 can be outputted as first amplified signal 320. Pre-driver 302 can also be configured to perform signal conditioning such as equalization (e.g., adjust frequency response) and/or filtering (e.g., removing unwanted frequencies) and to reduce noise in upconverted signal 210. Pre-driver stage 302 can have a relatively less gain when compared with driver stage 304 and final stage 306. In one embodiment, pre-driver stage 302 can be implemented by a Gallium Arsenide (GaAs) device or GaAs transistor.

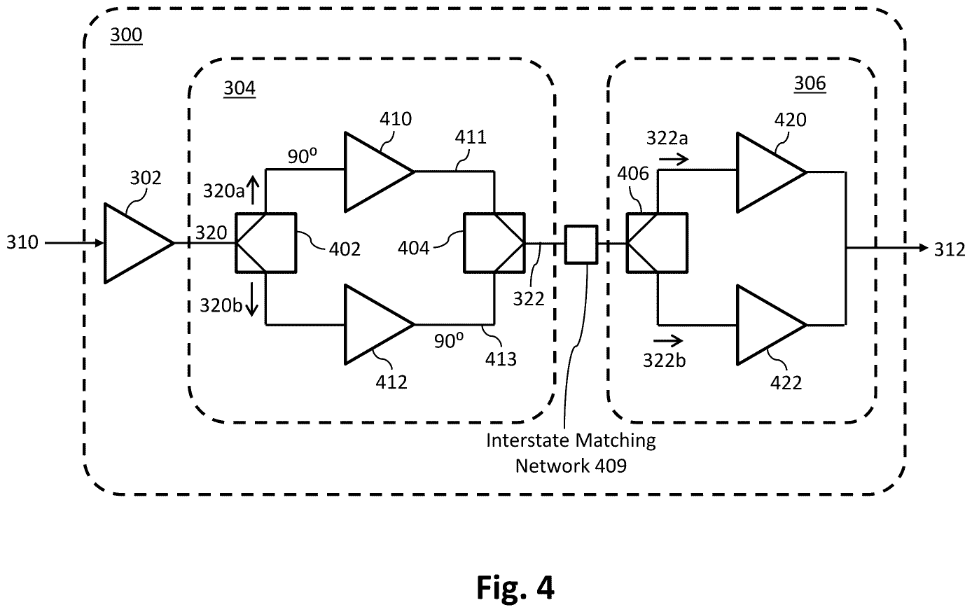

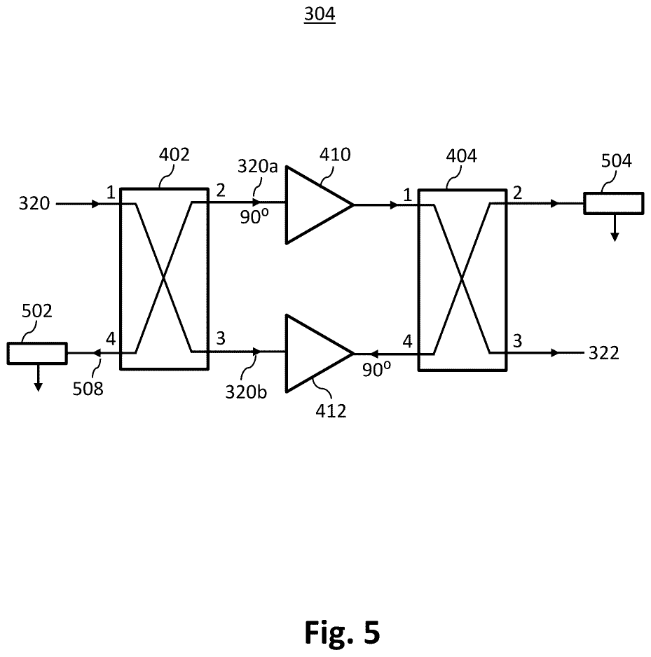

Driver stage 304 can receive first amplified signal 320. Driver stage 304 can be configured to boost the signal level of amplified signal 320 to a target level for an attached antenna (e.g., antenna 114 in FIG. 1 or antenna 214 in FIG. 2) to transmit wirelessly. The boosted signal generated by driver 304 can be outputted as second amplified signal 322. Driver stage 304 can be implemented with a balanced architecture by including a high absorption load to pre-driver stage 302 to eliminate reflection from driver stage 304 towards pre-driver stage 302, thus eliminating the need for an isolator. Details of driver stage 304 are presented in FIG. 4 and FIG. 5 below.

Final stage 306 can receive second amplified signal 322. Final stage 306 can be configured to further boost second amplified signal 322 to generate output amplified signal 312. Final stage 306 can output amplified signal 312 to a load, such as antenna 114 in FIG. 1 or antenna 214 in FIG. 2. Final stage 306 can be configured to output amplified signal 312 while maintaining relatively low distortion and high fidelity. In one or more embodiments, final stage 306 can include one or more power matching networks for matching the impedance of amplifier module 300 to the impedance of the load receiving output amplified signal 312 in order to maximize power transmission efficiency.

FIG. 4 is a diagram showing details of a three stage power amplifier with balanced driver stage in one embodiment. Descriptions of FIG. 4 can reference components shown in FIG. 1 to FIG. 3. In an example embodiment shown in FIG. 4, driver stage 304 can include a hybrid coupler 402, a hybrid coupler 404, an amplifier 410 and an amplifier 412. In one embodiment, amplifiers 410, 412 can be class AB amplifiers. Final stage 306 can include a splitter 406, an amplifier 420 and an amplifier 422. Final stage 306 can be implemented by a Doherty amplifier such that amplifier 420 can be a peak amplifier and amplifier 422 can be a main amplifier. In one embodiment, amplifier 420 can be a class C power amplifier and amplifier 422 can be a class AB power amplifier. In one or more embodiments, amplifiers 410, 412, 420, 422 can be implemented by Gallium Nitride (GaN) devices or GaN transistors, including but not limited to Gallium Nitride Metal Semiconductor Field-effect transistors (GaN MESFET), GaN high-electron-mobility transistor (HEMT), GaN heterostructure field-effect transistor (HFET), etc.

In one embodiment, amplifier 420 can have a periphery size that ranges from the periphery size of amplifier 422 (e.g., device periphery ratio of 1:1) up to a periphery size equivalent to twice the periphery size of amplifier 422 (e.g., device periphery ratio of 1:2). When the periphery size is same as the periphery size of amplifier 422, final stage 306 can have a up to a periphery size equivalent to twice the periphery size of amplifier 422. In one embodiment, a drain voltage of pre-driver stage 302 can be 5 volts (V) and drain voltages of driver stage 304 and final stage 306 can be 50V.

Hybrid coupler 402 can receive first amplified signal 320 from pre-driver stage 302. Hybrid coupler 402 can be configured to generate intermediate signals 320a, 320b using first amplified signal 320. In one embodiment, hybrid coupler 402 can be a 90-degree hybrid coupler, or a quadrature coupler, configured as a power splitter to perform a 3-dB (e.g., equal) power split, such as dividing an input signal (e.g., first amplified signal 320) evenly between two output ports with 3 dB coupling. The output signals, such as intermediate signals 320a, 320b, can have a phase difference of 90 degrees. Intermediate signal 320a can be a 90-degree shift version of first amplified signal 320, and intermediate signal 320b can be identical to, and/or in-phase with, first amplified signal 320. Hybrid coupler 402 can further include a high absorption load (described in FIG. 5) that isolates one of the ports of hybrid coupler 402 such that reflections from driver stage 304 towards pre-driver stage 302 can be absorbed by the high absorption load.

Amplifier 410 can be configured to amplify intermediate signal 320a to generate an amplified intermediate signal 411. Amplifier 412 can be configured to amplify intermediate signal 320b to generate an amplified intermediate signal 413. Hybrid coupler 404 can be a 90-degree hybrid coupler, or a quadrature coupler, configured as a combiner to combine amplified intermediate signals 411, 413 to generate second amplified signal 322. In one embodiment, amplifiers 410, 412 can be identical such that amplifiers 410, 412 can perform the same level of amplification, such as increasing the amplitudes of intermediate signals 320a, 320b by the same amount.

In one or more embodiments, an interstage matching network 409 can be connected between the output of hybrid coupler 404 and the input of splitter 406 for performing impedance matching between driver stage 304 and final stage 306. Interstage matching network 409 can be implemented using relatively simple components that allow driver stage 304 to directly connect to final stage 306 without using RF hot vias. Interstage matching network 409 between driver stage 304 and final stage 306 can provide tunability and performance optimization of the overall power amplifier module 300. In one embodiment, implementation of interstage matching network 409 can include using copper coins to improve cooling of driver stage 304 and final stage 306.

Splitter 406 of final stage 306 can receive second amplified signal 322 from hybrid coupler 404. Splitter 406 can split second amplified signal 322 into intermediate signals 322a, 322b. Intermediate signals 322a, 322b can be provided to amplifiers 420, 422 to drive amplifiers 420, 422, respectively. Amplifiers 420, 422 can amplify intermediate signals 322a, 322b and the outputs of amplifiers 420, 422 can be combined to form output signal 312.

FIG. 5 is a diagram showing another example implementation of a balanced driver stage of a three stage power amplifier with balanced driver stage in one embodiment. Descriptions of FIG. 5 can reference components shown in FIG. 1 to FIG. 4. In an example embodiment shown in FIG. 5, driver stage 304 can be implemented by a balanced amplifier architecture with hybrid coupler 402 configured as a power splitter and hybrid coupler 404 configured as a combiner.

First amplified signal 320 can be received by Port 1 (“1”) of hybrid coupler 402. Port 1 and Port 4 (“4”) of hybrid coupler 402 are at a 180-degree in-phase relationship. In an aspect, when a signal is applied to Port 1 and Port 4 of hybrid coupler 402 is terminated with a load 502, as shown in FIG. 5, the termination can cause power to be equally split between Port 2 (“2”) and Port 3 (“3”) of hybrid coupler 402. Therefore, first amplified signal 320 being received at Port 1 of hybrid coupler 402 is divided between the two output ports, Port 2 and Port 3 with half the power flowing to Port 2 (e.g., amplified signal 320a) and the other half flowing to Port 3 (e.g., intermediate signal 320b). Any reflection from mismatches at the output ports of hybrid coupler 402, such as Port 2 and Port 3, can flow to Port 4. Port 4 of hybrid coupler 402 can be configured as an isolation port that terminates standing waves and reflections into load 502. In one embodiment, load 502 can be a 50-ohm load resistor.

Intermediate signal 320a amplified by amplifier 410 can be received by Port 1 (“1”) of hybrid coupler 404. Intermediate signal 320b amplified by amplifier 412 can be received by Port 4 (“4”) of hybrid coupler 404. The phases of intermediate signals 320a, 320b are 90 degrees out-of-phase with each other. In an aspect, Port 3 (“3”) is 90 degrees out-of-phase with Port 1, and this phase mismatch can cause the powers to add to the output port, Port 3, and the mismatch can be absorbed by a load 504 connected to an isolated Port 2 (“2”). Therefore, hybrid coupler 404 is configured as a combiner that combines intermediate signals 320a, 320b amplified by amplifiers 410, 412 to generate second amplified signal 322.

The capability of the balanced driver topology of driver stage 304 to absorb reflections can allow a pre-driver (e.g., pre-driver stage 302) to be integrated and absorbed into a single power amplifier module without a need for isolation components. The isolation internal to driver stage 304 can enhances the power and temperature stability of the active devices using the three-stage power amplifier shown herein. The three-stage power amplifier shown herein can also enable higher gain for applications that require the higher gain. Also, the three-stage power amplifier shown herein can leverages GaN technology in both driver and final stages, thus enables improved overall RF performance (e.g., bandwidth, efficiency, output power). GaN devices in the driver and final stages can provide higher cut-off frequency, reduce device parasitic, and provide higher power density when compared to conventional devices such as Silicon-based lateral double-diffused metal-oxide semiconductor (Si LDMOS).

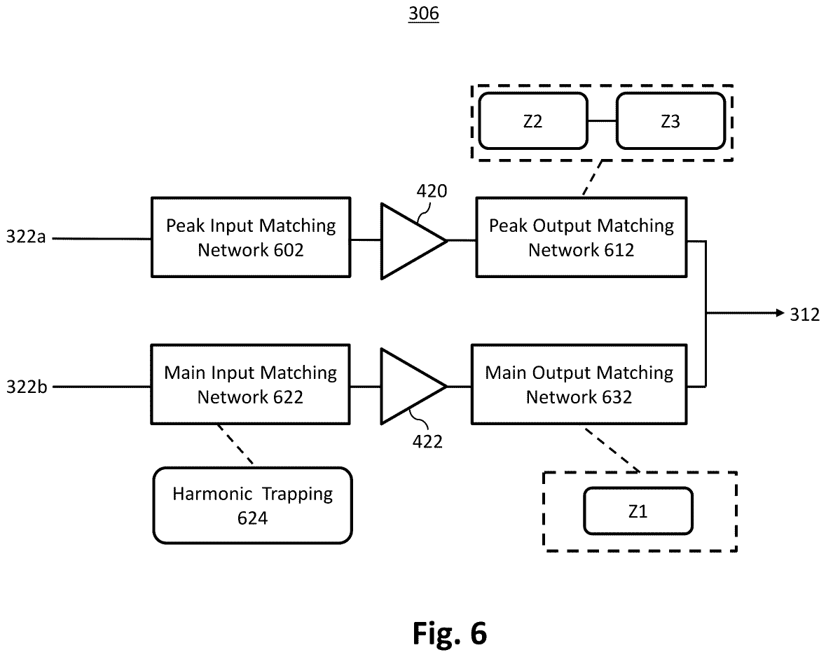

FIG. 6 is a diagram showing an example implementation of a final stage of a three stage power amplifier with balanced driver stage in one embodiment. Descriptions of FIG. 6 can reference components shown in FIG. 1 to FIG. 5. In an aspect, a final stage of conventional power amplifier modules may not include a peak output matching network before the signals of the peak path and main path are combined, and can include an impedance transformer matching networking to perform impedance matching between the final stage and the load (e.g., antenna) receiving the amplified signal from the final stage. The implementation of final stage 306 shown in FIG. 6 can provide a baseband matching topology that is integrated within the power amplifier module 300, which allows for relatively low envelope impedance and can maximum instantaneous bandwidth (IBW) operation with optimal linearity.

In an example embodiment shown in FIG. 6, final stage 306 can be implemented using amplifiers 420, 422, a peak input matching network 602, a peak output matching network 612, a main input matching network 622 and a main output matching network 632. In one embodiment, the configuration of final stage 306 shown in FIG. 6 can optimize optimal back off match of the main amplifier (e.g., amplifier 422), wideband off state impedance of the peak amplifier (e.g., amplifier 420), peak power match of the main and peak amplifiers, and output second harmonic match of the main and peak amplifiers at peak power.

In one embodiment, the electrical length of the main output matching network 632 can be designed to be between 45 and 135°, with 90° at center design frequency. The main output matching network 632 can be implemented as a one section matching network with a characteristic impedance Z1 that can be optimized to maximize the overall performance of the power amplifier module 300 across wide bandwidth. The main output matching network 632 can be implemented using, for example, surface mount components, microstrip lines, or a combination of both.

In one embodiment, the electrical length of the peak output matching network 612 can be designed to be between 135 and 225°, with 180° at center design frequency. The peak output matching network 612 can include two sections of matching networks (e.g., Z2, Z3) and can be implemented using surface mount components, microstrip lines, or a combination of both. The characteristic impedances Z2 and Z3 of each section in the output peak matching network 612 can be optimized to maximize the overall performance of power amplifier module 300 across wide bandwidth.

As a result of including peak output matching network 612 between the output of the peak amplifier (e.g., amplifier 420) and the combination point of the outputs from the peak and main path of the Doherty configuration in final stage 306, the output from the peak and main paths can be directly combined into a 50-ohm impedance with no extra impedance transformer after the combination. Hence, a 50-ohm input/output with DC blocking cap and baseband matching inside the power amplifier module 300 can be realized without extra matching networks or elements required outside of the power amplifier module 300 and can provide ease of integration in massive multiple input multiple output (MIMO) systems.

The input peak matching network 612 and the input main matching network 622 can be implemented by microstrip and surface mount technology (SMT)-based matching or delay networks that can provide optimal input match of the main and peak paths for wideband gain performance. In one embodiment, input main matching network 622 can include a harmonic trapping circuit 624 to boost an efficiency of the power amplifier module 300 by trapping the second harmonics of intermediate signal 322b prior to amplifier 420 receiving intermediate signal 322b. The main and peak paths can have two separate phasing networks to minimize the impact of overmold package and process variation, such that a distributed delay compensation can be provided. Overall, the incorporation of the output peak matching network 632 and the harmonic trap performed by main input matching network 622 can improve efficiency of power amplifier module 300 by improving the linearity of the power amplifier module 300. The configuration of final stage 306 shown in FIG. 6 can optimize optimal back off match of the main amplifier (e.g., amplifier 422), wideband off state impedance of the peak amplifier (e.g., amplifier 420), peak power match of the main and peak amplifiers and output second harmonic match of the main and peak amplifiers at peak power.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. An integrated circuit comprising:
a pre-driver stage configured to amplify an input signal to generate a first amplified signal;
a driver stage configured to:
split the first amplified signal into a first intermediate signal and a second intermediate signal, wherein the first intermediate signal and the second intermediate signal are out-of-phase with each other;
absorb reflections resulted from mismatches between the first intermediate signal and the second intermediate signal;
amplify the first intermediate signal to generate a first amplified intermediate signal;
amplify the second intermediate signal to generate a second amplified intermediate signal, wherein the first amplified intermediate signal and the second amplified intermediate signal are out-of-phase with each other;
absorb reflections resulted from mismatches between the first amplified intermediate signal and the second amplified intermediate signal;
combine the first amplified intermediate signal and the second intermediate amplified signal to generate a second amplified signal; and
a final stage configured to amplify the second amplified signal to generate an output amplified signal.

2. The integrated circuit of claim 1, wherein the driver stage comprises:
a first hybrid coupler configured to:
split the first amplified signal into the first intermediate signal and the second intermediate signal;
absorb reflections resulted from mismatches between the first intermediate signal and the second intermediate signal;
a first amplifier configured to amplify the first intermediate signal to generate the first amplified intermediate signal;
a second amplifier configured to amplify the second intermediate signal to generate the second amplified intermediate signal;
a second hybrid coupler configured to:
absorb reflections resulted from mismatches between the first amplified intermediate signal and the second amplified intermediate signal; and
combine the first amplified intermediate signal and the second intermediate amplified signal to generate the second amplified signal.

3. The integrated circuit of claim 2, wherein the first hybrid coupler and the second hybrid coupler are quadrature couplers.

4. The integrated circuit of claim 2, wherein:
the first amplifier is implemented by a first Gallium Nitride (GaN) device;
the second amplifier is implemented by a second GaN device; and
the first amplifier and the second amplifier are configured to perform the same level of amplification.

5. The integrated circuit of claim 1, wherein the pre-driver stage is implemented by a Gallium Arsenide (GaAs) device.

6. The integrated circuit of claim 1, wherein the final stage is implemented by a Doherty amplifier comprising a first GaN device configured as a peak amplifier and a second GaN device configured as a main amplifier.

7. The integrated circuit of claim 1, wherein the final stage comprises:
a peak amplifier;
a main amplifier;
a peak input matching network;
a peak output matching network comprising a first matching section and a second matching section, wherein the first matching section and the second matching section perform different impedance matching;
a main input matching network comprising a harmonic trapping section configured to trap a second harmonic of the second amplified signal; and
a main output matching network.

8. A system comprising:
a plurality of antennas;
a plurality of transmission channels, wherein a transmission channel comprises an amplifier module comprising:
a pre-driver stage configured to amplify an input signal to generate a first amplified signal;
a driver stage configured to:
split the first amplified signal into a first intermediate signal and a second intermediate signal, wherein the first intermediate signal and the second intermediate signal are out-of-phase with each other;
absorb reflections resulted from mismatches between the first intermediate signal and the second intermediate signal;
amplify the first intermediate signal to generate a first amplified intermediate signal;
amplify the second intermediate signal to generate a second amplified intermediate signal, wherein the first amplified intermediate signal and the second amplified intermediate signal are out-of-phase with each other;
absorb reflections resulted from mismatches between the first amplified intermediate signal and the second amplified intermediate signal;
combine the first amplified intermediate signal and the second intermediate amplified signal to generate a second amplified signal;
a final stage configured to:
amplify the second amplified signal to generate an output amplified signal; and
output the output amplified signal to an antenna among the plurality of antennas.

9. The system of claim 8, wherein the driver stage comprises:
a first hybrid coupler configured to:
split the first amplified signal into the first intermediate signal and the second intermediate signal;
absorb reflections resulted from mismatches between the first intermediate signal and the second intermediate signal;
a first amplifier configured to amplify the first intermediate signal to generate the first amplified intermediate signal;
a second amplifier configured to amplify the second intermediate signal to generate the second amplified intermediate signal;
a second hybrid coupler configured to:
absorb reflections resulted from mismatches between the first amplified intermediate signal and the second amplified intermediate signal; and
combine the first amplified intermediate signal and the second intermediate amplified signal to generate the second amplified signal.

10. The system of claim 9, wherein the first hybrid coupler and the second hybrid coupler are quadrature couplers.

11. The system of claim 9, wherein:
the first amplifier is implemented by a first Gallium Nitride (GaN) device;
the second amplifier is implemented by a second GaN device; and
the first amplifier and the second amplifier are configured to perform the same level of amplification.

12. The system of claim 8, wherein the pre-driver stage is implemented by a Gallium Arsenide (GaAs) device.

13. The system of claim 8, wherein the final stage is implemented by a Doherty amplifier comprising a first GaN device configured as a peak amplifier and a second GaN device configured as a main amplifier.

14. The system of claim 8, wherein the final stage comprises:
a peak amplifier;
a main amplifier;
a peak input matching network;
a peak output matching network comprising a first matching section and a second matching section, wherein the first matching section and the second matching section perform different impedance matching;
a main input matching network comprising a harmonic trapping section configured to trap a second harmonic of the second amplified signal; and
a main output matching network.

15. A system comprising:
a plurality of antennas;
a plurality of receiver channels configured to process signals being received by the plurality of antennas;
a plurality of transmission channels, wherein a transmission channel comprises an amplifier module comprising:
a pre-driver stage configured to amplify an input signal to generate a first amplified signal;
a driver stage configured to:
split the first amplified signal into a first intermediate signal and a second intermediate signal, wherein the first intermediate signal and the second intermediate signal are out-of-phase with each other;
absorb reflections resulted from mismatches between the first intermediate signal and the second intermediate signal;
amplify the first intermediate signal to generate a first amplified intermediate signal;
amplify the second intermediate signal to generate a second amplified intermediate signal, wherein the first amplified intermediate signal and the second amplified intermediate signal are out-of-phase with each other;
absorb reflections resulted from mismatches between the first amplified intermediate signal and the second amplified intermediate signal;
combine the first amplified intermediate signal and the second intermediate amplified signal to generate a second amplified signal;
a final stage configured to:
amplify the second amplified signal to generate an output amplified signal; and
output the output amplified signal to an antenna among the plurality of antennas.

16. The system of claim 15, wherein the driver stage comprises:
a first hybrid coupler configured to:
split the first amplified signal into the first intermediate signal and the second intermediate signal;
absorb reflections resulted from mismatches between the first intermediate signal and the second intermediate signal;
a first amplifier configured to amplify the first intermediate signal to generate the first amplified intermediate signal;
a second amplifier configured to amplify the second intermediate signal to generate the second amplified intermediate signal;
a second hybrid coupler configured to:
absorb reflections resulted from mismatches between the first amplified intermediate signal and the second amplified intermediate signal; and
combine the first amplified intermediate signal and the second intermediate amplified signal to generate the second amplified signal.

17. The system of claim 16, wherein the first hybrid coupler and the second hybrid coupler are quadrature couplers.

18. The system of claim 16, wherein:
the first amplifier is implemented by a first Gallium Nitride (GaN) device;
the second amplifier is implemented by a second GaN device; and
the first amplifier and the second amplifier are configured to perform the same level of amplification.

19. The system of claim 15, wherein the pre-driver stage is implemented by a Gallium Arsenide (GaAs) device.

20. The system of claim 15, wherein the final stage is implemented by a Doherty amplifier comprising a first GaN device configured as a peak amplifier and a second GaN device configured as a main amplifier, and the final stage comprises:
a peak input matching network;
a peak output matching network comprising a first matching section and a second matching section, wherein the first matching section and the second matching section perform different impedance matching;
a main input matching network comprising a harmonic trapping section configured to trap a second harmonic of the second amplified signal; and
a main output matching network.
